(19) United States
(12) Patent Application Publication
(10) Pub. No.: US 2003/0122219 A1
(43) Pub. Date: Jul. 3, 2003

(54) Inductor for radio communication module

(75) Inventor: Jae Yeong Park, Seoul (KR)

Correspondence Address: FLESHNER & KIM, LLP, P.O. Box 221200, Chantilly, VA, 20153-1200, US

(73) Assignee: LG Electronics Inc.

(21) Appl. No.: 10/322,505

(22) Filed: Dec. 19, 2002

(30) Foreign Application Priority Data
Dec. 24, 2001 (KR) P 2001-84367

(51) Int. Cl. H01F 5/00; H01P 3/08; H01L 29/00

(52) U.S. Cl. 257/531; 333/246; 336/200

(57) ABSTRACT

Disclosed is an inductor for a radio communication module enabling to be less affected by parasitics of a substrate as well as have a great cross-sectional area. The present invention includes a plurality of first and second conductive pads on a substrate, a plurality of first conductive bonding wires connecting the first and second conductive pads in diagonal directions, respectively, and a plurality of second conductive bonding wires connecting the first and second conductive pads confronting each other, respectively.

This application claims the benefit of the Korean Application No. P2001-84367 filed on Dec. 24, 2001, which is hereby incorporated by reference.

### BACKGROUND OF THE INVENTION

1. Field of the Invention

The present invention relates to an inductor, and more particularly, to an inductor for a module in a RF communication system.

2. Discussion of the Related Art

Recently, as RF radio communication systems prevail in use abruptly, demands on RF Modules required for these systems increase. The RF module generally includes active elements such as transistors and passive elements such as inductors, capacitors, resistors, and the like. Specifically, the inductor among the various elements used for constructing the RF module is an element hardly manufactured by a simple process as well as an element difficult to be inexpensive.

A planar inductor is integrated on a substrate and is easily affected by the substrate. Namely, the planar inductor has a great electric wave loss due to a conductivity of the substrate as well as barely has a great inductance due to parasitic capacitance of the substrate. Even if the substrate includes quartz, GaAs, ceramic, alumina, or the like to have less influence on the planar inductor, the influence of the substrate on the planar inductor is inevitable.

Moreover, a solenoid inductor has a limitation in increasing its cross-sectional area. If a twined number of the solenoid is increased, parasitic capacitance increases as well as a resonance frequency decreases. Hence, an available frequency of the inductor is lowered, resistance increases, and a Q (quality) factor decreases.

Recently, a RF micro-inductor, which has a substrate loss less than that of the planar inductor and is less affected by parasitics than the planar inductor, is under development by a new technology of micromachining. Yet, the RF micro-inductor fails to be applied to MMIC (monolithic microwave integrated circuit) requiring GaAs.

FIG. 1 illustrates a bird's-eye view of a solenoid inductor according to a related art, and FIG. 2 illustrates a layout of the solenoid inductor in FIG. 1.

Referring to FIG. 1 and FIG. 2, a suspended solenoid type inductor includes a bottom-conductor 3, a via 4, a to-conductor 5, and a supporting post 2. They are constructed using four masks. And, an air gap is small due to the limitation of the process. Hence, the inductor is still affected by the a substrate 1 and is unable to have a great cross-sectional area. For such reasons, the inductor according to the related are fails to have great inductance.

### SUMMARY OF THE INVENTION

Accordingly, the present invention is directed to an inductor for a RF communication module that substantially obviates one or more problems due to limitations and disadvantages of the related art.

An object of the present invention is to provide an inductor for a radio communication module enabling to be less affected by parasitics of a substrate as well as have a great cross-sectional area.

Another object of the present invention is to provide an inductor for a radio communication module enabling to have a simple structure to simplify a manufacturing process as well as reduce a product cost.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an inductor for a radio communication module according to the present invention includes a plurality of first and second conductive pads on a substrate, a plurality of first conductive bonding wires connecting the first and second conductive pads in diagonal directions, respectively, and a plurality of second conductive bonding wires connecting the first and second conductive pads confronting each other, respectively.

Preferably, each of the first conductive bonding wires leaves a first height from the substrate and each of the second conductive bonding wires leaves a second height greater than the first height from the substrate.

Preferably, the substrate comprises a material selected from the group consisting of quartz, ceramic, alumina, GaAs, and silicon of high resistance.

More preferably, the inductor further includes an insulating layer on the substrate.

Preferably, the substrate comprises silicon.

More preferably, the inductor further includes an insulating layer on the substrate wherein a predetermined portion of the substrate is removed.

More preferably, the inductor further includes a metal layer on the substrate and an insulating layer on the metal layer wherein a predetermined portion of the insulating layer is removed.

More preferably, the insulating layer is selected from the group consisting of BCB, polyimide, and epoxy.

Preferably, the inductor further includes contact means connected to a first one of the first conductive pads and a last one of the second conductive pads, respectively.

In another aspect of the present invention, an inductor for a radio communication module includes a plurality of conductive pads on a substrate, a spiral inductor line having both ends connected to the conductive pads respectively, and a conductive bonding wire connecting the conductive pad inside the spiral inductor line to the conductive pad outside the spiral inductor line, the conductive bonding wire leaving a predetermined height from the substrate.

Preferably, the conductive pads includes a first conductive pad connected to the end of the spiral inductor line outside the spiral inductor line, a second conductive pad connected to the other end of the spiral inductor line inside the spiral inductor line, and a third conductive pad connected to the second conductive pad through the conductive bonding wire outside the spiral inductor line.

Preferably, the substrate comprises a material selected from the group consisting of quartz, ceramic, alumina, GaAs, and silicon of high resistance.

More preferably, the inductor further includes an insulating layer on the substrate.

Preferably, the substrate comprises silicon.

More preferably, the inductor further includes an insulating layer on the substrate wherein a predetermined portion of the substrate is removed.

More preferably, the inductor further includes a metal layer on the substrate and an insulating layer on the metal layer wherein a predetermined portion of the insulating layer is removed.

More preferably, the insulating layer is selected from the group consisting of BCB, polyimide, and epoxy.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a bird's-eye view of a solenoid inductor according to a related art;

FIG. 2 illustrates a layout of the solenoid inductor in FIG. 1;

FIG. 3 illustrates a layout of a solenoid type inductor according to the present invention;

FIG. 4 illustrates a cross-sectional view of a solenoid type inductor in FIG. 3 along a cutting line A-A′;

FIGS. 5 to 7 illustrate cross-sectional views of various modifications of the inductor in FIG. 4;

FIG. 8 illustrates a layout of a solenoid type inductor according to another embodiment of the present invention;

FIG. 9 illustrates a cross-sectional view of a solenoid type inductor in FIG. 8 along a cutting line B-B′;

FIG. 10 illustrates a layout of a spiral inductor according to the present invention;

FIG. 11 illustrates a cross-sectional view of a spiral inductor in FIG. 10 along a cutting line C-C′;

FIGS. 12 to 15 illustrate cross-sectional views of various modifications of the inductor in FIG. 11;

FIG. 16 illustrates a picture of a solenoid type inductor according to the present invention;

FIG. 17 illustrates a characteristic graph of a solenoid type inductor according to the present invention;

FIG. 18 illustrates a layout of a solenoid type transformer having the embodiment of the present invention applied thereto; and

FIG. 19 illustrates a layout of a spiral transformer having the embodiment of the present invention applied thereto.

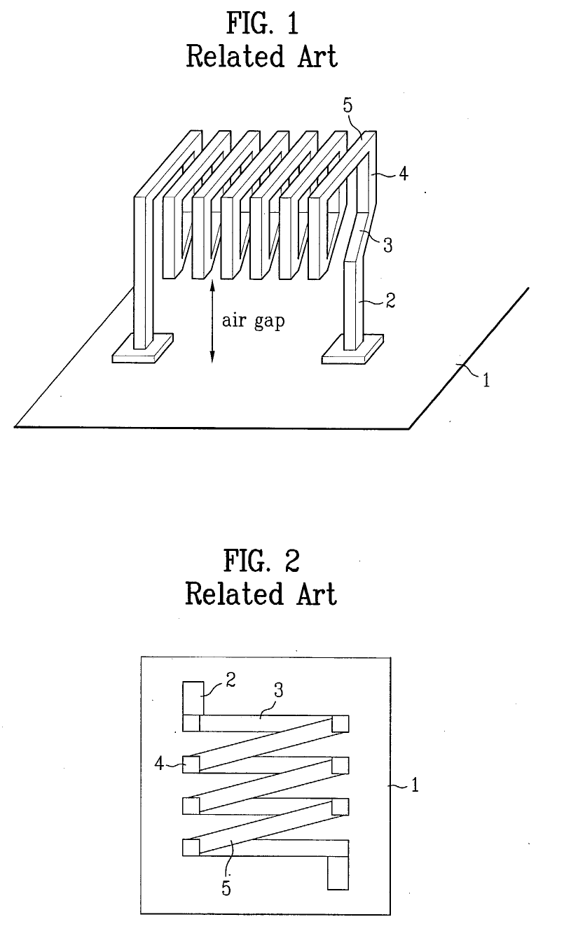

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

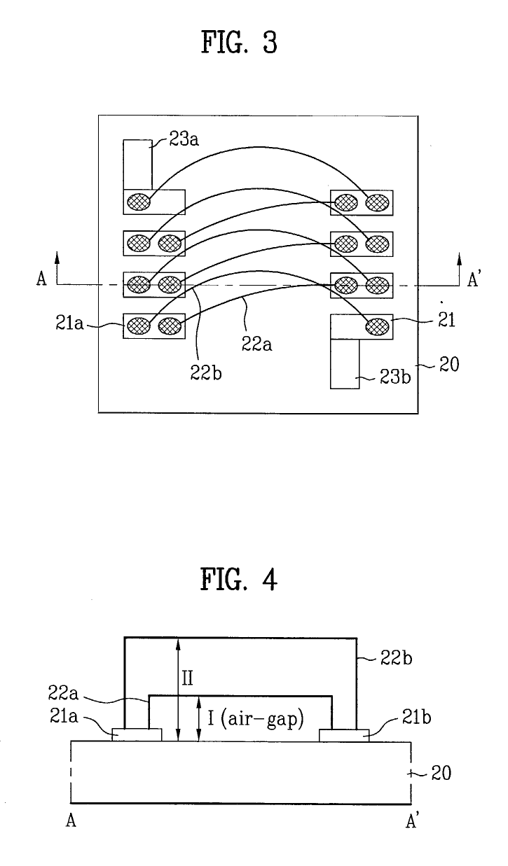

FIG. 3 illustrates a layout of a solenoid type inductor according to the present invention, and FIG. 4 illustrates a cross-sectional view of a solenoid type inductor in FIG. 3 along a cutting line A-A′.

Referring to FIG. 3, a plurality of first conductive pads 21a are arranged in a line on a substrate 20 made of quartz, ceramic, GaAs, or silicon of high resistance. And, a plurality of second conductive pads 21b are arranged on the substrate 20 in a line, leaving a predetermined distance from the former line. In this case, the substrate 20 having a great resistance enables to reduce an electric signal loss caused by the substrate 20. Moreover, the first and second conductive pads 21a and 21b are formed by electroplating, whereby a manufacturing process can be simplified.

First conductive bonding wires 22a are formed to connect the first and second conductive pads 21a and 21b to each other, respectively to separate from the substrate 20 to secure an air gap. And, second conductive bonding wires 22b are formed to connect the first and second conductive pads 21a and 21b to each other, respectively to separate from the substrate 20. In this case, the second conductive bonding wires 22b are formed to be higher than the first conductive bonding wires 22a. The first and second conductive bonding wires 22a and 22b are bonded to the first and second conductive pads 21a and 21b by an automatic wire bonding machine.

In this case, the locations of the first and second conductive bonding wires 22a and 22b are different from each other. Namely, the first conductive bonding wires 22a, as shown in FIG. 4, should leave a predetermined height I from the substrate to secure the air gap sufficiently, and the second conductive bonding wires 22b should leave the other height II greater than the height I from the substrate 20. Since the first and second conductive bonding wires 22a and 22b playing a role of a solenoid are sufficiently separated from the substrate 20, the influence of parasitics of the substrate is reduced as well as a cross-sectional area of the inductor is increased. Therefore, the inductor according to the present invention enables to have a great inductance.

Moreover, in order for the first and second conductive bonding wires 22a and 22b to play a role of the solenoid, the first and second conductive bonding wires 22a and 22b are connected to the different conductive pads 21a and 21b, respectively. For instance, the first conductive wires 21a connect the first and second conductive pads 21a and 21b which are diagonally disposed from each other, and the second conductive bonding wires 22b connect the first and second conductive pads 21a and 21b confronting each other. In other words, each of the first conductive bonding wires 22a connects the (n+1)^{th} conductive pad 21a to the n^{th} second conductive wire 21b, while each of the second conductive bonding wires 22b connects the n^{th} first conductive pad 21a to the n^{th} second conductive bonding wire 21b.

Besides, the first one of the first conductive pads 21a and the last one of the second conductive pads 21b are connected to contact means 23a and 23b, respectively in order to connect the above-constructed inductor to another circuit.

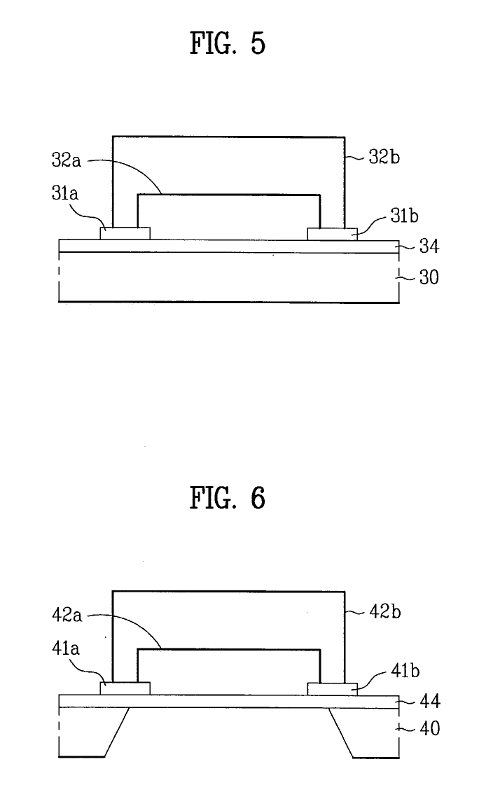

FIGS. 5 to 7 illustrate cross-sectional views of various modifications of the inductor in FIG. 4.

Referring to FIG. 5, an insulating layer 34 is formed on a substrate 30 including quartz, ceramic, alumina, GaAs, silicon of high resistance, or the like. A plurality of first conductive pads 31a are arranged on the insulating layer 34 to form one line, and a plurality of second conductive pads 31b are arranged on the insulating layer to form the other line leaving a predetermined distance from the former line. A plurality of first conductive bonding wires 32a connect the first conductive pads 31a to the second conductive pads 31b to separate from the insulating layer 34 to secure an air gap. And, a plurality of second conductive bonding wires 32b connect the first conductive pads 31a to the second conductive pads 32b to separate from the insulating layer 34 farther than the first conductive bonding wires 32a.

Referring to FIG. 6, unlike the inductor shown in FIG. 5, an insulating layer 44 is formed on a general silicon substrate 40. And, the silicon substrate 40 corresponding to an area where an inductor will be formed is selectively removed. Namely, the silicon substrate 40 under first and second conductive bonding wires 42a and 42b is removed by back surface etch, thereby enabling to reduce the influence of parasitics of the substrate 40. First and second conductive pads 41a and 41b are formed on the insulating layer 44 by electroplating, and the first and second conductive bonding wires 42a and 42b are formed to connect the first conductive pads 41a to the second conductive pads 41b, respectively.

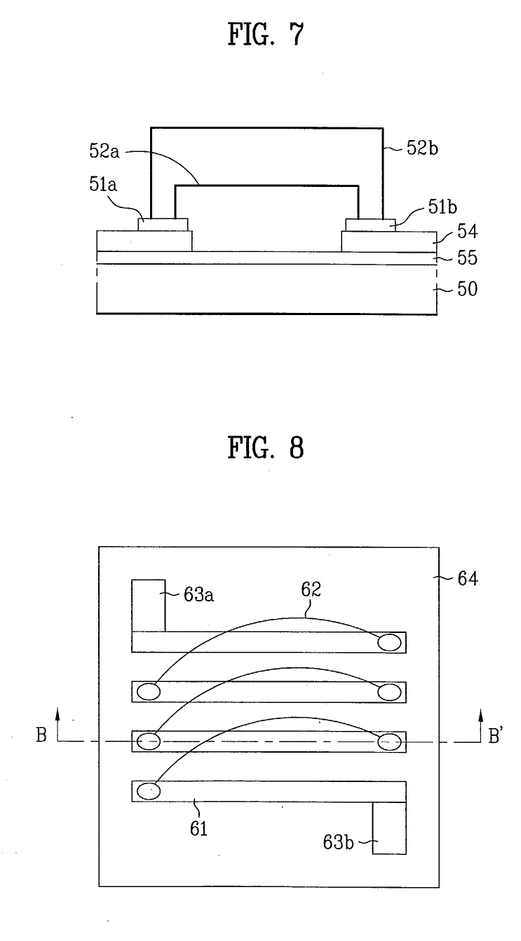

Referring to FIG. 7, a metal layer 55 is formed on a silicon substrate 50, and an insulating layer 54 is formed on the metal layer 55. In this case, the metal layer 55 plays a role in shielding the influence caused by the silicon substrate 50. The insulating layer 54 is formed of an organic material such as BCD (benzocyclobutene based polymer), polyimide, epoxy, and the like, and formed to be thicker than the metal layer 55. After the insulating layer 54 is deposited, the insulating layer 54 on the area where the inductor will be formed, i.e., under first and second bonding wires 52a and 52b, is selectively removed. First and second conductive pads 51a and 51b are formed on the remaining insulating layer 54, and the first and second conductive bonding wires 52a and 52b are formed to connect the first conductive pads 51a to the second conductive pads 51b.

Therefore, the present invention enables to form a great air gap between the inductor and the substrate using a wire bonding technique as well as an inductor having a great cross-sectional area according to the location and shape of the conductive bonding wires. Moreover, the present invention reduces the number of etching steps requiring masks, thereby simplifying the manufacturing process.

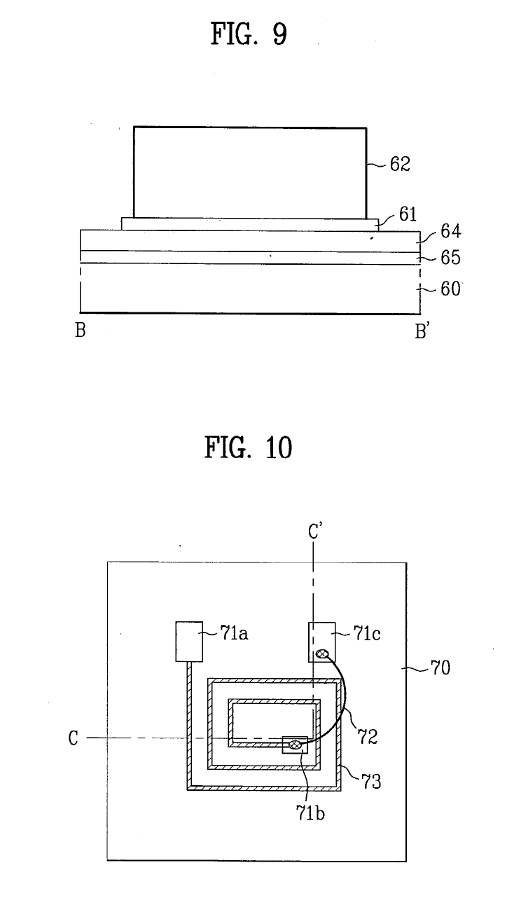

FIG. 8 illustrates a layout of a solenoid type inductor according to another embodiment of the present invention, and FIG. 9 illustrates a cross-sectional view of a solenoid type inductor in FIG. 8 along a cutting line B-B′.

Referring to FIG. 8 and FIG. 9, a metal layer 65 is formed on a silicon substrate 60, and an insulating layer 64 is formed thick on the metal layer 65. And, conductor lines 61 are formed on the insulating layer 64 by electroplating. In this case, first and last ones of the conductor lines 61 are connected to contact means 63a and 63b, respectively. Moreover, conductive bonding wires 62 connecting the conductor lines 61 to each other are formed using an automatic wire bonding machine.

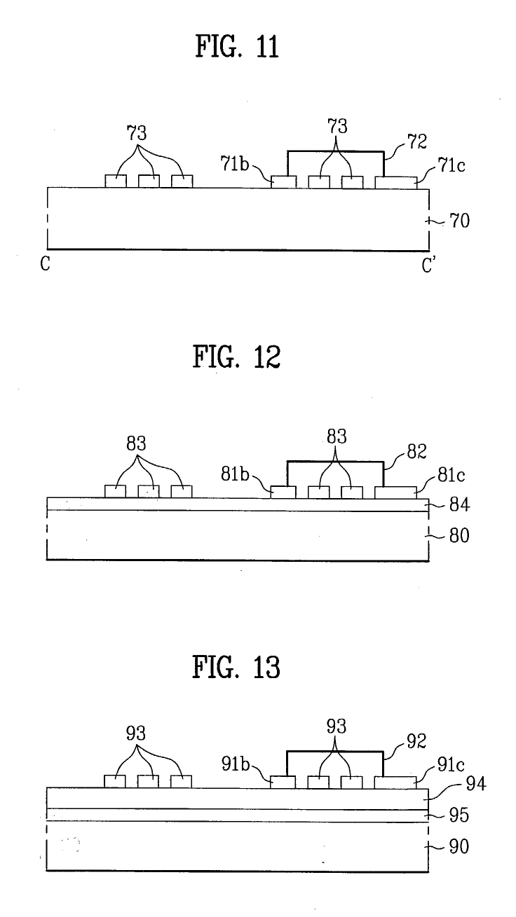

FIG. 10 illustrates a layout of a spiral inductor according to the present invention, and FIG. 11 illustrates a cross-sectional view of a spiral inductor in FIG. 10 along a cutting line C-C′.

Referring to FIG. 10, a spiral inductor line 73 is formed on a substrate 70 including quartz, ceramic, alumina, GaAs, or silicon of high resistance using a single mask. A first conductive pad 71a connected to an outer end of the spiral inductor line 73 is formed on the substrate 70, and a second conductive pad 71b connected to an inner end of the spiral inductor line 73 is formed on the substrate 70. Moreover, a third conductive pad 71c is formed on a periphery of the spiral inductor line 73. The third conductive pad 71c is connected to the second conductive pad 71b through a conductive bonding wire 72. In this case, the spiral inductor line 73 and the first to third conductive pads 71a, 71b, and 71c are formed by electroplating. The conductive bonding wire 72 is separated from the substrate 70 and the spiral inductor line 73 to leave a predetermined height.

FIGS. 12 to 15 illustrate cross-sectional views of various modifications of the inductor in FIG. 11.

Referring to FIG. 12, an insulating layer 84 is formed on a substrate 80 including quartz, ceramic, alumina, GaAs, or silicon of high resistance, and a spiral inductor line 83 and conductive pads 81b and 81c are formed on the insulating layer 84. And, a bonding wire 82 connects the conductive pads 81b and 81c to leave a predetermined height from the insulating layer 84 and spiral inductor line 83.

Referring to FIG. 13, a metal layer 95 is formed on a silicon substrate 90, and a thick insulating layer 94 is formed of an organic material such as BCD, polyimide, epoxy, and the like on the metal layer 95. A spiral inductor line 93 and conductive pads 91b and 91c are formed on the insulating layer 94. And, a conductive bonding wire 92 connects the conductive pads 91b and 91c to each other to leave a predetermined height from the insulating layer 94 and spiral inductor line 93.

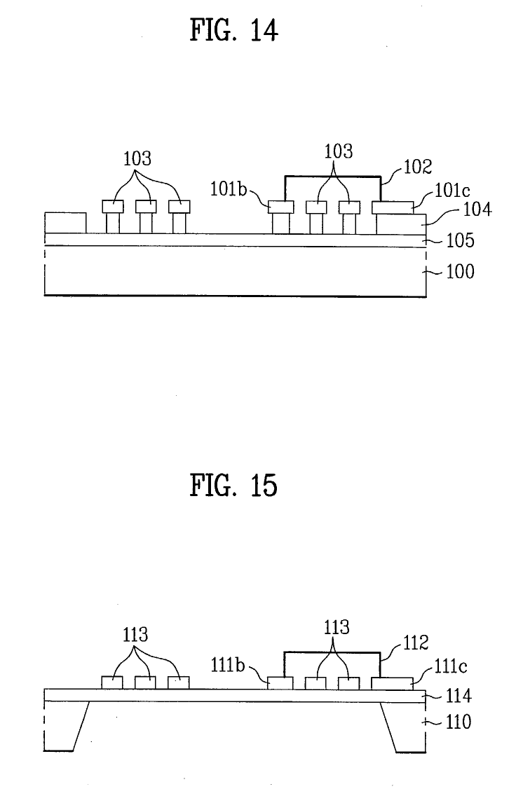

Referring to FIG. 14, a metal layer 105 is formed on a silicon substrate 100, and a thick insulating layer 104 is formed of an organic material such as BCD, polyimide, epoxy, and the like on the metal layer 105. After a spiral inductor line 103 and conductive pads 101b and 101c are formed on the insulating layer 104 by electroplating, the insulating layer 104 adjacent to the spiral inductor line 103 is selectively removed by dry etch. In this case, the spiral inductor line 103 is used as a mask. And, a conductive bonding wire 102 connecting the conductive pads 101b and 101c to each other is formed.

Referring to FIG. 15, an insulating layer 114 is formed on a silicon substrate 110, and the silicon substrate 110 corresponding to an area where a spiral inductor line 113 will be formed is selectively removed. A spiral inductor line 113 and conductive pads 111b and 111c are formed on the insulating layer 114 by electroplating. A conductive bonding wire 112 connecting the conductive pads 111b and 111c to each other is formed.

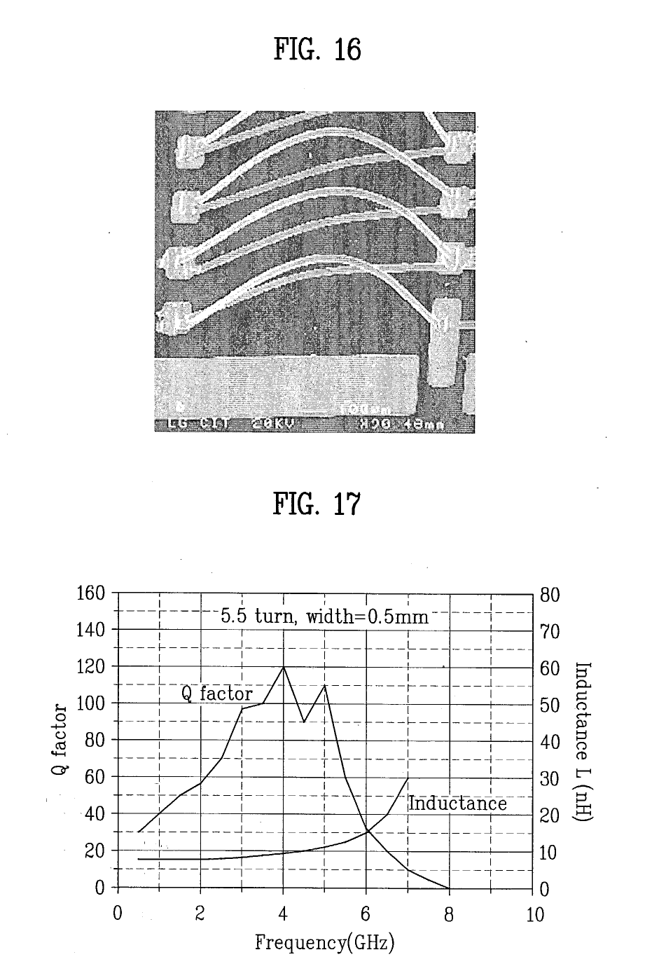

FIG. 16 illustrates a picture of a solenoid type inductor according to the present invention, and FIG. 17 illustrates a characteristic graph of a solenoid type inductor according to the present invention.

Referring to FIG. 17, when a solenoid has a twining turn of 5.5 and a width of 0.5 mm, a Q factor of 120 is attained at a self-resonance frequency of 4 GHz and an inductance of 30 nH is attained at 7 GHz. Compared to the related art inductor having the Q factor of 50˜60, the solenoid type inductor according to the present invention has excellent characteristics.

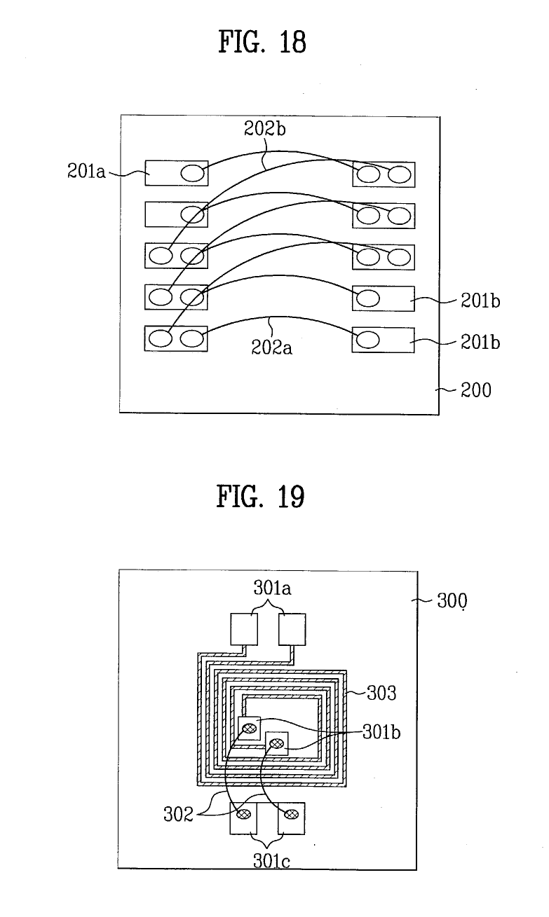

FIG. 18 illustrates a layout of a solenoid type transformer having the embodiment of the present invention applied thereto, and FIG. 19 illustrates a layout of a spiral transformer having the embodiment of the present invention applied thereto.

The fabricating method of the inductors according to the present invention is applied to the fabrication of transformers shown in FIG. 18 and FIG. 19. Yet, the solenoid type transformed, as shown in FIG. 18, differs from the inductor of the present invention in having two input terminals 201a and two output terminals 201b. This is because the transformer includes a pair of solenoids. Moreover, the spiral transformer, as shown in FIG. 19, includes a pair of spiral inductor lines 303 and input and output terminals 301a and 301b connected to a pair of the spiral inductor lines 303, respectively. Conductive pads 301c connected to the output pads 301b are formed, and conductive bonding wires 302 respectively connecting the output terminals 301b to the conductive pads 301c are formed.

Accordingly, the inductor for the radio communication module according to the present invention has the following effects or advantages.

First of all, since the inductor is formed using the conductive wires, the inductor can be integrated on the substrate3 including quartz, ceramic, alumina, GaAs, silicon of high resistance, or the like.

Secondly, the inductor according to the present invention includes the conductive wires separated from the substrate with a predetermined interval, thereby enabling to adjust the air gap and cross-sectional area of the inductor according to its shape and height with ease. Therefore, the present invention enables to manufacture the inductor having the great inductance, Q factor, and resonance frequency.

Thirdly, the inductor according to the present invention has the simple structure, needs the mask-using etching steps less than the related art method, and formed the conductive pads by electroplating to simplify the fabricating process as well as reduce the product cost.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An inductor for a radio communication module, comprising:
a plurality of first and second conductive pads on a substrate;
a plurality of first conductive bonding wires connecting the first and second conductive pads in diagonal directions, respectively; and
a plurality of second conductive bonding wires connecting the first and second conductive pads confronting each other, respectively.

2. The inductor of claim 1, wherein each of the first conductive bonding wires leaves a first height from the substrate and each of the second conductive bonding wires leaves a second height greater than the first height from the substrate.

3. The inductor of claim 1, wherein the substrate comprises a material selected from the group consisting of quartz, ceramic, alumina, GaAs, and silicon of high resistance.

4. The inductor of claim 3, further comprising an insulating layer on the substrate.

5. The inductor of claim 1, wherein the substrate comprises silicon.

6. The inductor of claim 5, further comprising an insulating layer on the substrate wherein a predetermined portion of the substrate is removed.

7. The inductor of claim 5, further comprising:
a metal layer on the substrate; and
an insulating layer on the metal layer wherein a predetermined portion of the insulating layer is removed.

8. The inductor of claim 7, wherein the insulating layer is formed of a material selected from the group consisting of BCB, polyimide, and epoxy.

9. The inductor of claim 1, further comprising contact means connected to a first one of the first conductive pads and a last one of the second conductive pads, respectively.

10. An inductor for a radio communication module, comprising:
a plurality of conductive pads on a substrate;
a spiral inductor line having both ends connected to the conductive pads respectively; and
a conductive bonding wire connecting the conductive pad inside the spiral inductor line to the conductive pad outside the spiral inductor line, the conductive bonding wire leaving a predetermined height from the substrate.

11. The inductor of claim 10, the conductive pads comprising:
a first conductive pad connected to the end of the spiral inductor line outside the spiral inductor line;
a second conductive pad connected to the other end of the spiral inductor line inside the spiral inductor line; and
a third conductive pad connected to the second conductive pad through the conductive bonding wire outside the spiral inductor line.

12. The inductor of claim 10, wherein the substrate comprises a material selected from the group consisting of quartz, ceramic, alumina, GaAs, and silicon of high resistance.

13. The inductor of claim 12, further comprising an insulating layer on the substrate.

14. The inductor of claim 10, wherein the substrate comprises silicon.

15. The inductor of claim 14, further comprising an insulating layer on the substrate wherein a predetermined portion of the substrate is removed.

16. The inductor of claim 14, further comprising:
a metal layer on the substrate; and
an insulating layer on the metal layer wherein a predetermined portion of the insulating layer is removed.

17. The inductor of claim 16, wherein the insulating layer is selected from the group consisting of BCB, polyimide, and epoxy.
